(19) United States
(12) Patent Application Publication
(10) Pub. No.: US 2017/0178758 A1
(43) Pub. Date: Jun. 22, 2017

(54) UNIFORM WAFER TEMPERATURE ACHIEVEMENT IN UNSYMMETRIC CHAMBER ENVIRONMENT

(71) Applicant: Applied Materials, Inc., Santa Clara, CA (US)

(72) Inventors: Sungwon HA, Palo Alto, CA (US); Paul CONNORS, San Mateo, CA (US); Jianhua ZHOU, Campbell, CA (US); Juan Carlos ROCHA-ALVAREZ, San Carlos, CA (US); Kwangduk Douglas LEE, Redwood City, CA (US); Ziqing DUAN, Sunnyvale, CA (US); Nicolas J. BRIGHT, Arlington, WA (US); Feng BI, Cupertino, CA (US)

(21) Appl. No.: 15/369,219

(22) Filed: Dec. 5, 2016

Related U.S. Application Data
(60) Provisional application No. 62/269,599, filed on Dec. 18, 2015.

(51) Int. Cl. G21F 3/00; C23C 16/458; C23C 16/50; C23C 16/448

(52) U.S. Cl. CPC G21F 3/00; C23C 16/448; C23C 16/458; C23C 16/50

(57) ABSTRACT

The present disclosure generally relates to a radiation shield for a process chamber which improves substrate temperature uniformity. The radiation shield may be disposed between a slit valve door of the process chamber and a substrate support disposed within the process chamber. In some embodiments, the radiation shield may be disposed under a heater of the process chamber. Furthermore, the radiation shield may block radiation and/or heat supplied from the process chamber, and in some embodiments, the radiation shield may absorb and/or reflect radiation, thus providing improved temperature uniformity as well as improving a planar profile of the substrate.

### CROSS-REFERENCE TO RELATED APPLICATIONS

This application claims priority to U.S. Provisional Patent Application Ser. No. 62/269,599, filed on Dec. 18, 2015, which herein is incorporated by reference.

### BACKGROUND

Field

Embodiments disclosed herein generally relate to semiconductor processing, and more specifically to an apparatus for providing uniform heat radiation loss in a process chamber.

Description of the Related Art

Plasma enhanced chemical vapor deposition (PECVD) is used to deposit thin films on a substrate, such as a semiconductor wafer or a transparent substrate. PECVD is generally accomplished by introducing a precursor gas or gas mixture into a vacuum chamber containing a substrate. The precursor gas or gas mixture is typically directed downwardly through a distribution plate situated near the top of the chamber. The precursor gas or gas mixture in the chamber is energized (e.g., excited) into a plasma by applying a power, such as a radio frequency (RF) power, to an electrode in the chamber from one or more power sources coupled to the electrode. The excited gas or gas mixture reacts to form a layer of material on a surface of the substrate. The layer may be, for example, a passivation layer, a gate insulator, a buffer layer, and/or an etch stop layer.

PECVD processing further allows deposition at lower temperatures, which is often critical in the manufacture of semiconductors. The lower temperatures also allow for the deposition of organic coatings, such as plasma polymers, that have been used for nanoparticle surface functionalization. Temperatures associated with the process chamber may be unsymmetrical, mainly due to the presence of a slit valve opening through which the substrate is transferred into and out of the process chamber. The non-symmetry causes non-uniform radiation heat loss from the heater and the substrate, and further creates higher temperature variations within the substrate. Promoting more uniform radiation heat loss may improve film uniformity on the substrate.

Therefore, what is needed in the art is radiation shield for improving substrate temperature uniformity.

### SUMMARY

The present disclosure generally relates to a radiation shield for a processing chamber which improves substrate temperature uniformity. The radiation shield may be disposed between a slit valve of the processing chamber and a substrate support disposed within the processing chamber. In some embodiments, the radiation shield may be disposed under a heater of the processing chamber. Furthermore, the radiation shield may block radiation and/or heat supplied from the processing chamber, and in some embodiments, the radiation shield may absorb and/or reflect radiation, thus providing improved temperature uniformity as well as improving a planar profile of the substrate.

In one embodiment, a radiation shield for a processing chamber is disclosed. The radiation shield includes a disk-shaped radiation plate having a plurality of holes disposed therethrough and a radiation stem coupled to the radiation plate.

In another embodiment, a processing chamber is disclosed. The processing chamber includes a substrate support disposed in a processing volume within the processing chamber, a substrate support stem coupled to the substrate support, a slit valve disposed within a wall of the processing chamber, and a lift system coupled to a base of the substrate support stem. The processing chamber further includes a radiation shield. The radiation shield includes a radiation plate and a radiation stem. The radiation plate is disposed between the slit valve and the substrate support. The radiation stem is coupled to the radiation plate, and is disposed between the lift system and the radiation plate.

In yet another embodiment, a processing chamber is disclosed. The processing chamber includes a substrate support disposed in a processing volume of the processing chamber, a substrate support stem coupled to the substrate support, a slit valve disposed within a wall of the processing chamber, and a lift system coupled to a base of the substrate support stem. The processing chamber further includes a radiation shield and a plasma source coupled to the processing chamber. The radiation source includes a radiation plate and a radiation stem. The radiation plate is disposed between the slit valve and the substrate support. The radiation stem is coupled to the radiation plate, and is disposed between the lift system and the radiation plate.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a schematic cross-sectional view of one embodiment of a process chamber having a radiation shield.

FIG. 2 is a plan view of a radiation shield, according to one embodiment.

FIG. 3 is a schematic cross-sectional view of a processing volume of the process chamber of FIG. 1 having the radiation shield of FIG. 2 disposed therein, according to one embodiment.

To facilitate understanding, identical reference numerals have been used, where possible, to designate identical elements that are common to the Figures. It is contemplated that elements and features of one embodiment may be beneficially incorporated in other embodiments without further recitation.

### DETAILED DESCRIPTION

The embodiments disclosed herein generally relate to a radiation shield for a process chamber which improves substrate temperature uniformity. The radiation shield may be disposed between a slit valve door of the process chamber and a substrate support disposed within the process chamber. In some embodiments, the radiation shield may be disposed under a heater of the process chamber. Furthermore, the radiation shield may block radiation and/or heat supplied from the process chamber, and in some embodiments, the radiation shield may absorb and/or reflect radiation, thus providing improved temperature uniformity as well as improving a planar profile of the substrate.

Embodiments herein are illustratively described below in reference to use in a PECVD system configured to process substrates, such as a PECVD system, available from Applied Materials, Inc., Santa Clara, Calif. However, it should be understood that the disclosed subject matter has utility in other system configurations such as etch systems, other chemical vapor deposition systems, and any other system in which a substrate is exposed to radiation and/or heat within a process chamber. It should further be understood that embodiments disclosed herein may be practiced using process chambers provided by other manufacturers and chambers using multiple shaped substrates. It should also be understood that embodiments disclosed herein may be practiced using process chambers configured to process substrates of various sized and dimensions.

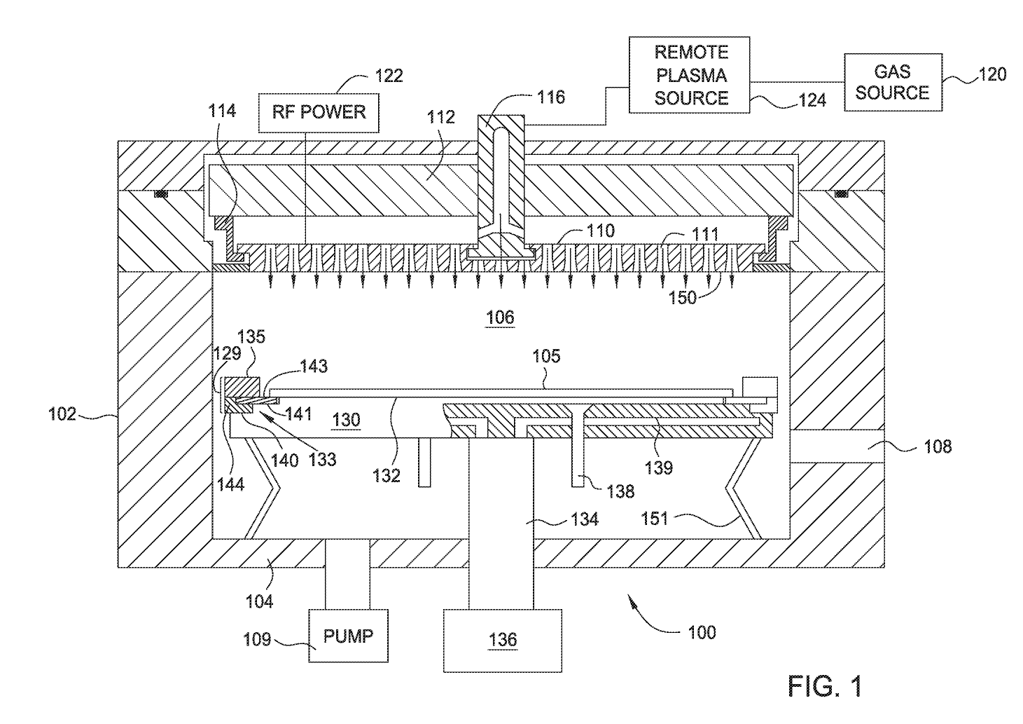

FIG. 1 is a schematic cross-section view of one embodiment of a chamber 100 for forming electronic devices. The chamber 100 is a PECVD chamber. As shown, the chamber 100 includes walls 102, a bottom 104, a diffuser 110, and a substrate support 130. The walls 102, bottom 104, diffuser 110, and substrate support 130 collectively define a processing volume 106. The processing volume 106 is accessed through a sealable slit valve opening 108 formed through the walls 102 such that a substrate 105 may be transferred in and out of the chamber 100. The dimensions of the substrate 105 may vary.

In one embodiment, the substrate support 130 comprises a ceramic material. For example, the substrate support 130 may comprise aluminum oxide or anodized aluminum. The substrate support 130 includes a substrate receiving surface 132 for supporting the substrate 105. A stem 134 is coupled on one end to the substrate support 130. The stem 134 is coupled on an opposite end to a lift system 136 to raise and lower the substrate support 130.

In operation, the spacing between a top surface of the substrate 105 and a bottom surface 150 of the diffuser 110 may be between about 10 mm and about 30 mm. In other embodiments, the spacing may be between about 10 mm and about 20 mm. In still other embodiments, the spacing may be between about 10 mm and about 15 mm, such as about 13 mm. In other embodiments, the spacing may be less than about 10 mm or greater than about 30 mm.

In one embodiment, heating and/or cooling elements 139 may be used to maintain the temperature of the substrate support 130 and substrate 105 thereon during deposition. For example, the temperature of the substrate support 130 may be maintained at less than about 400° C. In one embodiment, the heating and/or cooling elements 139 may utilized to control the substrate temperature to less than about 100° C., such as between about 20° C. and about 90° C.

Lift pins 138 are moveably disposed through the substrate support 130 to move the substrate 105 to and from the substrate receiving surface 132 to facilitate substrate transfer. The substrate support 130 may also include grounding straps 151 to provide RF grounding at the periphery of the substrate support 130.

A gas confiner assembly 129 is disposed around the periphery of the substrate support 130. In one embodiment, the gas confiner assembly 129 includes a cover frame 133 and a gas confiner 135. As shown, the gas confiner assembly 129 is positioned on a ledge 140 and a ledge 141 formed in the periphery of the substrate support 130. In other embodiments, the gas confiner assembly 129 may be positioned adjacent to the substrate support 130 in an alternative manner, such as, for example through the use of a fastener (not shown). For example, the fastener may fasten the gas confiner assembly 129 to the substrate support 130. The gas confiner assembly 129 is configured to decrease high deposition rates on the edge regions of the substrate 105. In one embodiment, the gas confiner assembly 129 reduces high deposition rates at the edges of the substrate 105 without affecting the large range uniformity profile of the substrate 105.

As shown, the cover frame 133 is positioned on and disposed around the periphery of the substrate receiving surface 132 of the substrate support 130. The cover frame 133 comprises a base 144 and a cover 143. In some embodiments, the base 144 and the cover 143 may be separate components. In other embodiments, the base 144 and the cover 143 may form a unitary body. The base 144 and the cover 143 may comprise a non-metal material, such as a ceramic or glass material. The base 144 and/or the cover 143 may be comprised of a material having a low impedance. In some embodiments, the base 144 and/or the cover 143 may have a high dielectric constant. For example, the dielectric constant may be between greater than about 3.6. In some embodiments, the dielectric constant may be between about 3.6 and about 9.5, such as between about 9.1 and about 9.5. In some embodiments the dielectric constant may be greater than or equal to 9.1. Representative ceramic materials include aluminum oxide, anodized aluminum. The base 144 and cover 143 may be comprised of the same or different materials. In some embodiments, the base 144 and/or the cover 143 comprise the same material as the substrate receiving surface 132.

In some embodiments, the cover frame 133 is secured on the substrate support 130 by gravity during processing. In some embodiments where the cover frame 133 is secured by gravity, one or more notches (not shown) in the bottom surface of the cover frame 133 are aligned with one or more posts (not shown) protruding from the substrate support 130. Alternatively or additionally, one or more notches (not shown) in the substrate support 130 may align with one or more posts (not shown) protruding from the bottom surface of the cover frame 133 to secure the cover frame 133 to the substrate support 130. In other embodiments, the cover frame 133 is fastened to the substrate. In one embodiment, the cover frame 133 includes one or more locating pins (not shown) for aligning with the gas confiner 135. In other embodiments, the cover frame 133 is secured to the substrate support by an alternate technique. The cover frame 133 is configured to cover the substrate support 130 during processing. The cover frame 133 prevents the substrate support 130 from being exposed to plasma.

Embodiments disclosed herein optionally include a gas confiner 135. The gas confiner 135 may be positioned above the cover frame 133. As shown, the gas confiner 135 is positioned directly above and in contact with the cover frame 133. The gas confiner 135 may comprise a non-metal or glass. For example, the gas confiner 135 may comprise a ceramic, such as aluminum oxide (Al₂O₃).

The diffuser 110 is coupled to a backing plate 112 at the periphery by a suspension 114. The diffuser 110 may also be coupled to the backing plate 112 by one or more center supports 116 to help prevent sag and/or control the straightness/curvature of the diffuser 110. A gas source 120 is coupled to the backing plate 112. The gas source 120 may provide one or more gases through a plurality of gas passages 111 formed in the diffuser 110 and to the processing volume 106. Suitable gases may include, but are not limited to, a silicon-containing gas, a nitrogen-containing gas, an oxygen-containing gas, an inert gas, or other gases. Representative silicon-containing gases include silane (SiH₄). Representative nitrogen-containing gases include nitrogen (N₂), nitrous oxide (N₂O) and ammonia (NH₃). Representative oxygen-containing gases include oxygen (O₂). Representative inert gases include argon (Ar). Representative other gases include, for example, hydrogen (H₂).

A vacuum pump 109 is coupled to the chamber 100 to control the pressure within the processing volume 106. An RF power source 122 is coupled to the backing plate 112 and/or directly to the diffuser 110 to provide RF power to the diffuser 110. The RF power source 122 may generate an electric field between the diffuser 110 and the substrate support 130. The generated electric field may form a plasma from the gases present between the diffuser 110 and the substrate support 130. Various RF frequencies may be used. For example, the frequency may be between about 0.3 MHz and about 200 MHz, such as about 13.56 MHz.

A remote plasma source 124, such as an inductively coupled remote plasma source, may also be coupled between the gas source 120 and the backing plate 112. Between processing substrates, a cleaning gas may be provided to the remote plasma source 124. The cleaning gas may be excited to a plasma within the remote plasma source 124, forming a remote plasma. The excited species generated by the remote plasma source 124 may be provided into the process chamber 100 to clean chamber components. The cleaning gas may be further excited by the RF power source 122 provided to flow through the diffuser 110 to reduce recombination of the dissociated cleaning gas species. Suitable cleaning gases include but are not limited to NF₃, F₂, and SF₆.

The chamber 100 may be used to deposit any material, such as a silicon-containing material. For example, the chamber 100 may be used to deposit one or more layers of amorphous silicon (a-Si), silicon nitride (SiNₓ), and/or silicon oxide (SiOₓ).

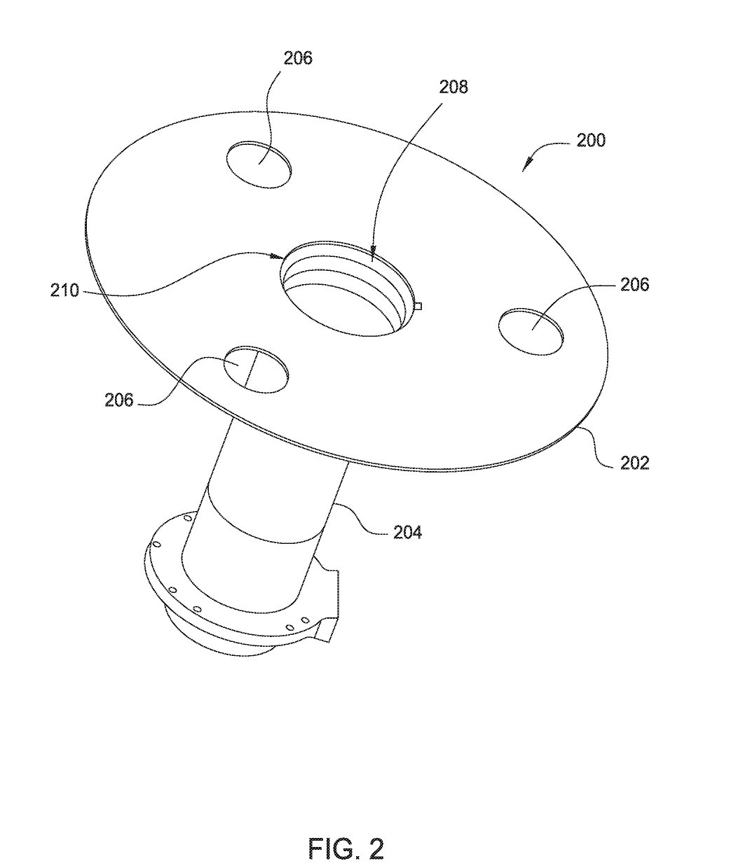

FIG. 2 is a plan view of a radiation shield 200 for a processing chamber, such as chamber 100. As shown, the radiation shield 200 may include a radiation plate 202 and a radiation stem 204. The radiation plate 202 may be circular or disk-shaped; however it is contemplated that other shapes of radiation plates 202 may be utilized. It is further contemplated that the radiation plate 202 may resemble or match the shape of the substrate support utilized within the specific processing device or processing chamber. In some embodiments, the radiation plate may have a diameter of between about 10 inches and about 20 inches, for example, about 14 inches. It is contemplated, however, that the radiation plate may have any suitable diameter.

The radiation plate 202 may comprise an aluminum oxide material or an aluminum nitride material. The radiation plate 202 may further include a plurality of holes 206 disposed therethrough. In some embodiments, the plurality of holes 206 may allow the lift pins 138, as described supra, to pass therethrough. In certain embodiments, each of the plurality of holes 206 may be disposed around the central axis of the radiation plate 202. In certain embodiments, the plurality of holes 206 may be evenly spaced apart. The radiation plate 202 may further include a hole 208 disposed in the center of the radiation plate 202. Hole 208 may surround the stem 134, thus allowing stem 134 to pass therethrough.

The radiation plate 202 may have a uniform thickness. In some embodiments, the radiation plate 202 may have a thickness of between about 25 mm and about 250 mm, for example, between about 50 mm and about 200 mm, such as about 100 mm. In certain embodiments, the radiation plate 202 may have a variable thickness of between about 25 mm and about 250 mm, for example, between about 50 mm and about 200 mm.

The radiation stem 204 may be a tubular member or a cylindrical member, and in some embodiments, the radiation stem 204 may have a hollow core. The radiation stem may be coupled to the radiation plate 202. The radiation stem 204 may be coupled at a first end 210 to the radiation plate 202 at the hole 208. The radiation stem 204 may comprise a quartz material or any other material suitable for use in semiconductor processing.

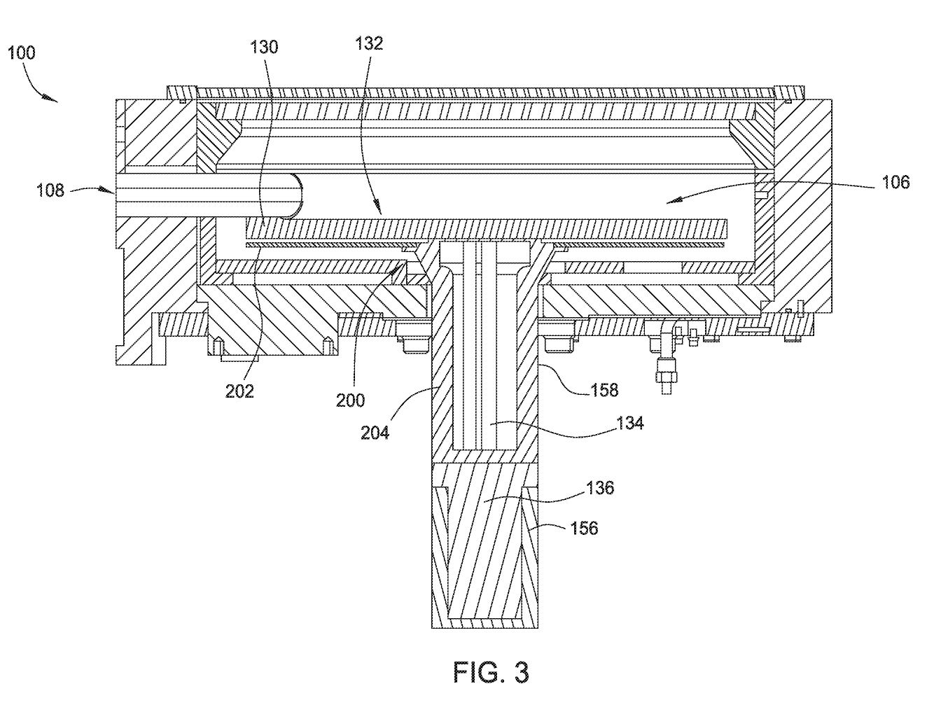

FIG. 3 is a schematic cross-sectional view of a processing volume 106 of the chamber 100 of FIG. 1. As shown, the processing volume 106 includes radiation shield 200 disposed therein. The radiation shield 200 may be disposed below the substrate receiving surface 132 of the substrate support 130. In some embodiments, the radiation plate 202 may be disposed between the slit valve opening 108 and the substrate support 130. In some embodiments, the radiation stem 204 may be disposed between the lift system 136 and the radiation plate 202. Furthermore, in some embodiments, the radiation stem 204 may support and/or encase the substrate support stem 134.

During processing, the radiation shield 200 may be disposed between the slit valve opening 108 and the substrate support 130 to avoid heat loss. As such, the radiation shield 200 may be disposed below the substrate support 130. Also, the radiation shield 200 may be engaged with and coupled to the substrate support 130, such that when the substrate support 130 raises and/or lowers the radiation shield also raises and/or lowers. Therefore, when the substrate support 130 is in the processing position (e.g., a raised position) the slit valve opening 108 is disposed below the radiation plate 202, thus avoiding heat loss.

Additionally, in some embodiments, the radiation stem 204 may be disposed between a cooling hub 156 and the slit valve opening 108. The cooling hub 156 may be disposed below the substrate support stem 134 and may provide cooling to the processing volume 106. Furthermore, a purge baffle 158 may be disposed within the processing volume 106. The purge baffle 158 may restrain the flow of a fluid or gas.

Testing was performed and results indicated that the use of the radiation shield 200, as described supra, reduced front to back temperatures within the processing chamber from 6° C. to 1° C. Furthermore, results indicated that a temperature profile of the substrate processed became approximately symmetric. Also, azimuthal temperature at 2 mm EE was reduced from 5.9° C. to 4.1° C.

During testing of the radiation shield 200, heater temperatures were increased by 90° C. and substrate temperatures were increased by 60° C. Heat loss to the bottom components (e.g., liners, pumping plate, slit valve opening, and shaft) was reduced by approximately 15%. Furthermore, heat loss to top and/or side components (e.g., FP and PPM stack) was increased by approximately 40% due to elevated heater and substrate temperatures.

Testing of the radiation shield 200 further indicated that, in semiconductor processing chambers comprising the radiation shield, the maximum substrate temperature achieved was about 584° C. while the maximum substrate temperature achieved in similar substrate processing chambers without the radiation shield was about 523° C. In semiconductor processing chambers comprising the radiation shield, the maximum heater temperature achieved was about 742° C. while the maximum heater temperature achieved in similar substrate processing chambers without the radiation shield was about 654° C.

Benefits the present disclosure further include that the radiation shield disclosed is coupled to the substrate support rather than to the slit valve opening. The radiation shield is disposed under the heater, therefore creating more uniform radiation and heating as well as improving the planar profile to the substrate. Additionally, the present disclosure may be utilized on any thermal blocking apparatus and/or on any PECVD processing chamber, including those from various manufacturers.

Additional benefits include that the lower temperature variation within the substrate, as well as the promotion of uniform heat loss, thus improving film uniformity on the substrate.

The aforementioned advantages are illustrative and not limiting. It is not necessary for all embodiments to have the aforementioned advantages. While the foregoing is directed to embodiments of the present disclosure, other and further embodiments of the disclosure may be devised without departing from the basic scope thereof, and the scope thereof is determined by the claims that follow.

What is claimed is:

1. A radiation shield for a processing chamber, comprising:
a disk-shaped radiation plate having a plurality of holes disposed therethrough; and
a radiation stem coupled to the disk-shaped radiation plate.

2. The radiation shield of claim 1, wherein the disk-shaped radiation plate comprises an aluminum oxide or an aluminum nitride material.

3. The radiation shield of claim 1, wherein the radiation stem comprises a quartz material.

4. The radiation shield of claim 1, wherein the disk-shaped radiation plate has a uniform thickness of between about 50 mm and about 150 mm.

5. The radiation shield of claim 1, wherein the disk-shaped radiation plate has a variable thickness of between about 50 mm and about 200 mm.

6. The radiation shield of claim 1, wherein the radiation stem is a tubular member with a hollow core.

7. A processing chamber, comprising:
a substrate support disposed in a processing volume within the processing chamber;
a substrate support stem coupled to the substrate support;
a lift system coupled to the substrate support stem; and
a radiation shield, comprising:
a radiation plate disposed below the substrate support; and
a radiation stem coupled to the radiation plate, wherein the radiation stem is disposed between the lift system and the radiation plate.

8. The processing chamber of claim 7, wherein the radiation plate is disk-shaped.

9. The processing chamber of claim 7, wherein the radiation plate has a plurality of holes disposed therethrough.

10. The processing chamber of claim 7, wherein the radiation plate comprises an aluminum oxide or an aluminum nitride material.

11. The processing chamber of claim 7, wherein the radiation stem comprises a quartz material.

12. The processing chamber of claim 7, wherein the processing chamber is a PECVD processing chamber.

13. The processing chamber of claim 7, wherein the radiation plate has a uniform thickness of between about 50 mm and about 150 mm.

14. The processing chamber of claim 7, wherein the radiation plate has a variable thickness of between about 50 mm and about 200 mm.

15. The processing chamber of claim 7, wherein the radiation stem is a tubular member with a hollow core.

16. The processing chamber of claim 15, wherein the radiation stem surrounds the substrate support stem.

17. A processing chamber, comprising:
a substrate support disposed in a processing volume of the processing chamber;
a substrate support stem coupled to the substrate support;
a lift system coupled to the substrate support stem;
a radiation shield, comprising:
a radiation plate disposed below the substrate support; and
a radiation stem coupled to the radiation plate, wherein the radiation stem is disposed between the lift system and the radiation plate; and
a plasma source coupled to the processing chamber.

18. The processing chamber of claim 17, wherein the radiation plate comprises an aluminum oxide or an aluminum nitride material.

19. The processing chamber of claim 17, wherein the radiation stem comprises a quartz material.

20. The processing chamber of claim 17, wherein the radiation plate has a uniform thickness of between about 50 mm and about 150 mm.
